(19) United States
(12) Patent Application Publication
(10) Pub. No.: US 2014/0120715 A1
(43) Pub. Date: May 1, 2014

(54) SEMICONDUCTOR MANUFACTURING METHOD, SEMICONDUCTOR STRUCTURE AND PACKAGE STRUCTURE THEREOF

(71) Applicant: CHIPBOND TECHNOLOGY CORPORATION, Hsinchu (TW)

(72) Inventors: Chih-Ming Kuo, Hsinchu County (TW); Lung-Hua Ho, Hsinchu City (TW); Kung-An Lin, Hsinchu City (TW); Sheng-Hui Chen, Taichung City (TW)

(73) Assignee: CHIPBOND TECHNOLOGY CORPORATION, Hsinchu (TW)

(21) Appl. No.: 14/147,891

(22) Filed: Jan. 6, 2014

Related U.S. Application Data
(62) Division of application No. 13/562,551, filed on Jul. 31, 2012.

(51) Int. Cl. H01L 21/768

(52) U.S. Cl. CPC H01L 21/76885
USPC 438/614

(57) ABSTRACT

A semiconductor manufacturing method includes providing a carrier having a metallic layer, wherein the metallic layer comprises a plurality of base areas and a plurality of outer lateral areas; forming a first photoresist layer; forming a plurality of bearing portions; removing the first photoresist layer to reveal the bearing portions, each bearing portion comprises a bearing surface having a first area and a second area; forming a second photoresist layer for revealing the first areas of the bearing surfaces; forming a plurality of connection portions, wherein the first areas of the bearing surfaces are covered by the connection portions to make each connection portion connect with each bearing portion to form a snap bump; removing the outer lateral areas of the metallic layer to make the base areas form a plurality of under bump metallurgy layers.

### FIELD OF THE INVENTION

The present invention is generally related to a semiconductor manufacturing method, which particularly relates to the semiconductor manufacturing method with snap bumps.

### BACKGROUND OF THE INVENTION

A conventional semiconductor package structure comprises a substrate, a chip and a plurality of solders. In conventional semiconductor package structure, bumps of the chip are electrically coupled with connection pads of the substrate through the solders. However, since modern mobile device gradually leads a direction of light and small, the spacing between adjacent bumps on the chip decreases as well. In the reflow process, the solders likely overflow toward adjacent bumps and leads to a short phenomenon therefore lowering the yield rate of products.

### SUMMARY

The primary object of the present invention is to provide a semiconductor manufacturing method including the steps of providing a carrier having a surface and a metallic layer formed on the surface, wherein the metallic layer comprises a plurality of base areas and a plurality of outer lateral areas located outside the base areas; forming a first photoresist layer on the metallic layer, wherein the first photoresist layer comprises a plurality of first openings; forming a plurality of bearing portions at the first openings; removing the first photoresist layer to reveal the bearing portions, each bearing portion comprises a bearing surface having a first area and a second area; forming a second photoresist layer on the metallic layer and covering the bearing portions with the second photoresist layer; wherein the second photoresist layer comprises a plurality of second openings for revealing the first areas of the bearing surfaces; forming a plurality of connection portions at the second openings and covering the first areas of the bearing surfaces with the connection portions to make each connection portion connect with each bearing portion so as to form a snap bump; removing the second photoresist layer to reveal the snap bumps; removing the outer lateral areas of the metallic layer to make the base areas of the metallic layer form a plurality of under bump metallurgy layers. Since each snap bump possesses the bearing portion and the connection portion, when the snap bumps couple to a substrate, the solders can be accommodated and constrained at the bearing portions so as to prevent solders from overflowing toward adjacent snap bumps to avoid electrical failure.

### DESCRIPTION OF THE DRAWINGS

FIG. 1 is a flow chart illustrating a semiconductor manufacturing method in accordance with a first preferred embodiment of the present invention.

FIGS. 2A to 2H are cross section diagrams illustrating a semiconductor manufacturing method in accordance with a first preferred embodiment of the present invention.

FIG. 3 is a cross section diagram illustrating a semiconductor structure in accordance with a second preferred embodiment of the present invention.

FIG. 4 is a cross section diagram illustrating a semiconductor structure in accordance with a third preferred embodiment of the present invention.

FIG. 5 is a cross section diagram illustrating a semiconductor package structure in accordance with a first preferred embodiment of the present invention.

### DETAILED DESCRIPTION OF THE INVENTION

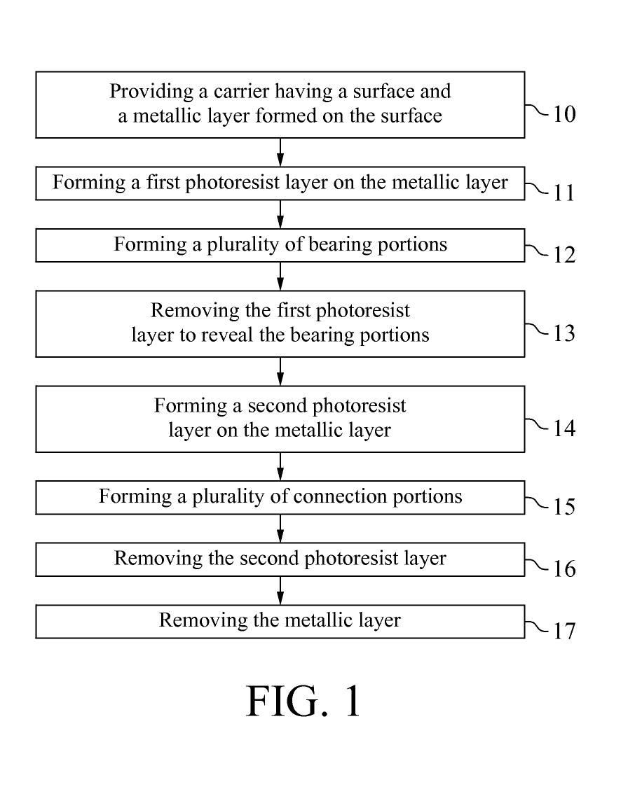

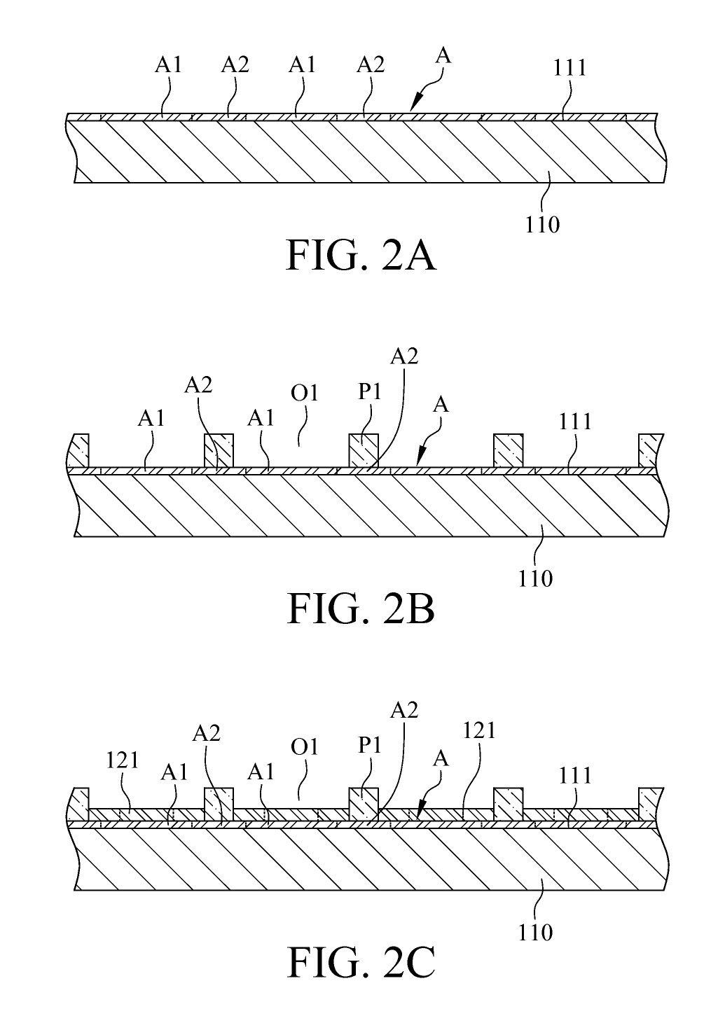

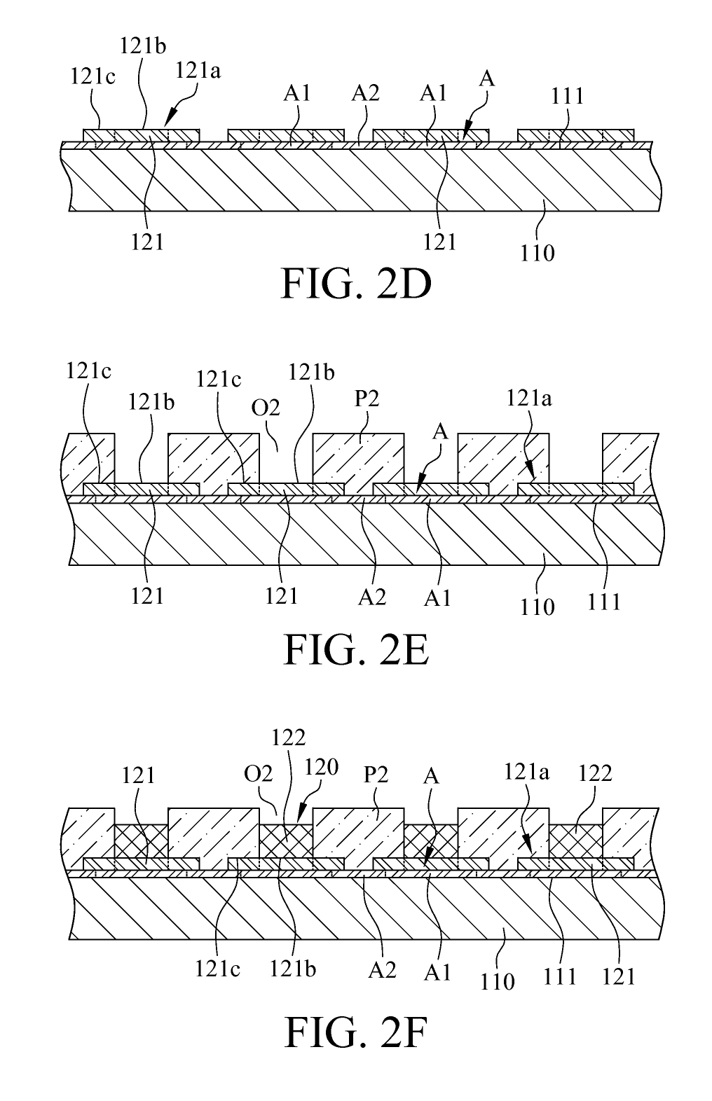

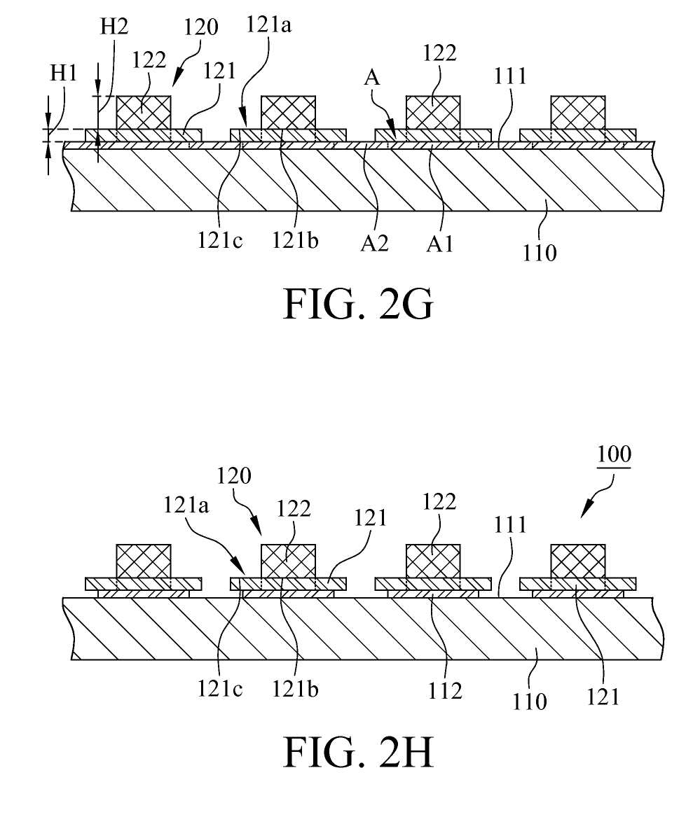

With reference to FIGS. 1 and 2A to 2H, a semiconductor manufacturing method in accordance with a first preferred embodiment of the present invention includes the steps as followed. First, referring to step 10 in FIG. 1 and FIG. 2A, providing a carrier 110 having a surface 111 and a metallic layer A formed on the surface 111, the metallic layer A comprises a plurality of base areas A1 and a plurality of outer lateral areas A2 located outside the base areas A1; next, referring to step 11 in FIG. 1 and FIG. 2B, forming a first photoresist layer P1 on the metallic layer A, wherein the first photoresist layer P1 comprises a plurality of first openings O1; thereafter, referring to step 12 in FIG. 1 and FIG. 2C, forming a plurality of bearing portions 121 at the first openings O1, the material of bearing portions 121 is selected from one of gold, nickel and copper; afterwards, referring to step 13 in FIG. 1 and FIG. 2D, removing the first photoresist layer P1 to reveal the bearing portions 121, each bearing portion 121 comprises a bearing surface 121a having a first area 121b and a second area 121c; next, with reference to step 14 in FIG. 1 and FIG. 2E, forming a second photoresist layer P2 on the metallic layer A and covering the bearing portions 121 with the second photoresist layer P2, wherein the second photoresist layer P2 comprises a plurality of second openings O2 for revealing the first areas 121b of the bearing surfaces 121a; then, referring to step 15 in FIG. 1 and FIG. 2F, forming a plurality of connection portions 122 at the second openings O2 and covering the first areas 121b of the bearing surfaces 122 with the connection portions 122 to make each connection portion 122 connect with each bearing portion 121 so as to form a snap bump 120, the material of the connection portions 122 is selected from one of gold, nickel or copper, wherein the material of the bearing portions 121 is the same or different with that of the connection portions 122; afterwards, referring to step 16 in FIG. 1 and FIG. 2G, removing the second photoresist layer P2 to reveal the snap bumps 120, in this embodiment, each bearing portion 121 comprises a first thickness H1, each connection portion 122 comprises a second thickness H2 larger than the first thickness H1, eventually, referring to step 17 in FIG. 1 and FIG. 2H, removing the outer lateral areas A2 of the metallic layer A to make the base areas A1 of the metallic layer A form a plurality of under bump metallurgy layers 112 therefore forming a semiconductor structure 100, wherein the material of the under bump metallurgy layers 112 is selected from one of titanium/copper, titanium-tungsten/copper or titanium-tungsten/gold.

A semiconductor structure 100 in accordance with a first embodiment of the present invention is illustrated in FIG. 2H. The semiconductor structure 100 at least includes a carrier 110 and a plurality of snap bumps 120. The carrier 110 comprises a surface 111 and a plurality of under bump metallurgy layers 112 formed on the surface 111, and the snap bumps 120 are formed on the under bump metallurgy layers 112. Each snap bump 120 comprises a bearing portion 121 and a connection portion 122 connected with the bearing portion 121, wherein each bearing portion 121 comprises a bearing surface 121a having a first area 121b and a second area 121c, and the first area 121b of each bearing surface 121a is covered with each connection portion 122. Since each snap bump 120 possesses the bearing portion 121 and the connection portion 122, when the snap bumps 120 couple to a substrate, the solders can be accommodated and constrained at the bearing portions 121 so as to prevent solders from overflowing toward adjacent snap bumps 120 to avoid electrical failure.

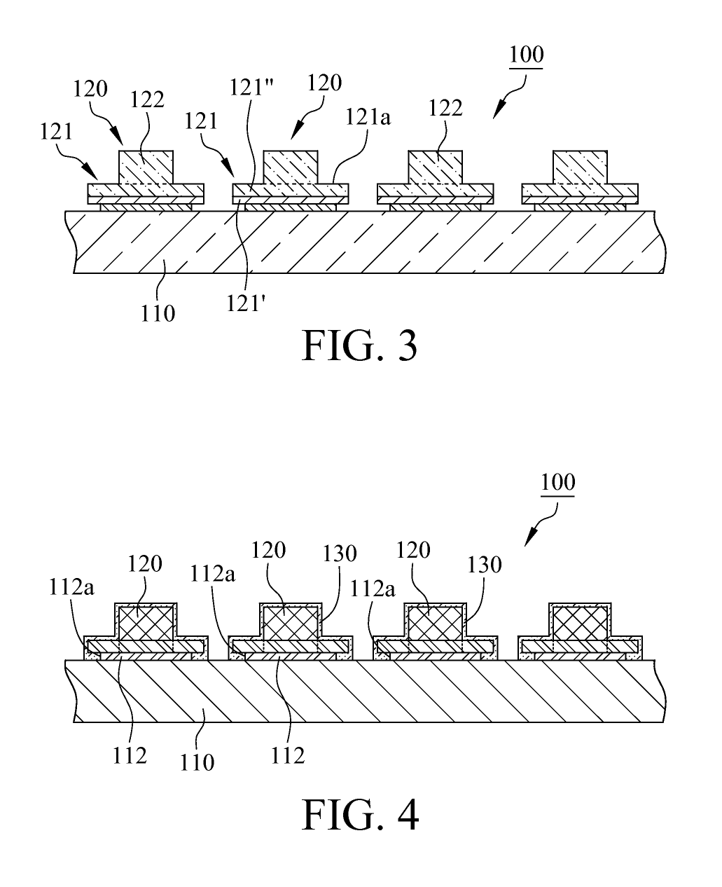

Furthermore, the semiconductor structure 100 in accordance with a second embodiment of the present invention is illustrated in FIG. 3, the semiconductor structure 100 at least includes a carrier 110 and a plurality of snap bumps 120, the primary difference between the second embodiment and the first embodiment is that each bearing portion 121 includes a first bearing layer 121′ and a second bearing layer 121″. In the step of forming a plurality of bearing portions 121 at the first openings O1, each first bearing layer 121′ is formed at each first opening O1 in advance, each second bearing layer 121″ is then formed on each first bearing layer 121′. In this embodiment, each second bearing layer 121″ comprises the bearing surface 121a.

Next, the semiconductor structure 100 in accordance with a third embodiment of the present invention is illustrated in FIG. 4. The semiconductor structure 100 at least includes a carrier 110, a plurality of snap bumps 120 and a gold plated layer 130, wherein the primary difference between the third embodiment and the first embodiment is that the semiconductor structure 100 further includes the gold plated layer 130, and each snap bump 120 is cladded by the gold plated layer 130. In this embodiment, each under bump metallurgy layer 112 comprises a ring surface 112a cladded by the gold plated layer 130, wherein the gold plated layer 130 is utilized for preventing the snap bumps 120 and the under bump metallurgy layers 112 from oxidation or damp.

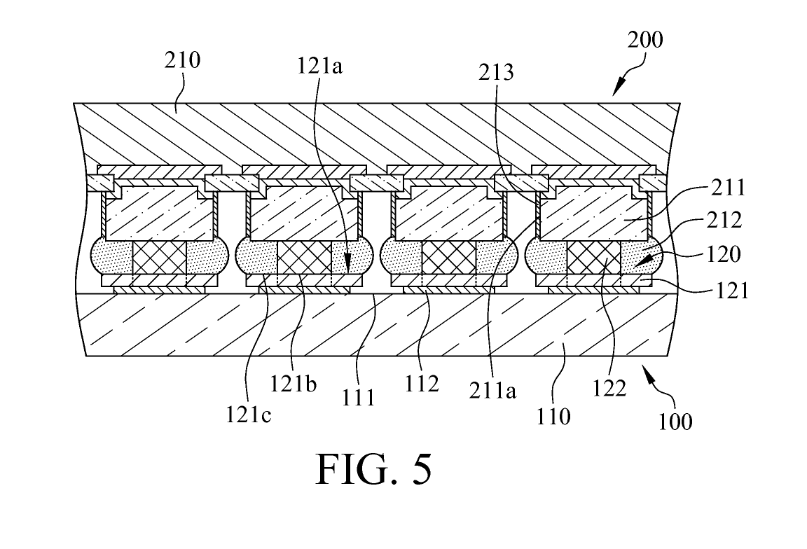

Otherwise, a semiconductor package structure 200 in accordance with a first embodiment of the present invention is illustrated in FIG. 5. The semiconductor package structure 200 includes a semiconductor structure 100 and a substrate 210, wherein the semiconductor structure 100 includes a carrier 110 and a plurality of snap bumps 120. The carrier 110 comprises a surface 111 and a plurality of under bump metallurgy layers 112 formed on the surface 111, and the snap bumps 120 are formed on the under bump metallurgy layers 112. Each snap bump 120 comprises a bearing portion 121 and a connection portion 122 connected with the bearing portion 121, wherein each bearing portion 121 comprises a bearing surface 121a having a first area 121b and a second area 121c, and the first area 121b of each bearing surface 121a is covered with each connection portion 122. The substrate 210 comprises a plurality of connection elements 211, a plurality of solders 212 and a plurality of metal rings 213, wherein each connection elements 211 comprises an outer lateral surface 211a. Each solder 212 is formed on each connection elements 211, each outer lateral surface 211a is cladded by each metal ring 213, and the connection elements 211 are coupled to the connection portions 122 of the snap bumps 120. The material of the metal rings 213 is gold. The connection portions 122 are cladded by the solders 212, wherein the solders 212 are in connection with the bearing portions 121 and the connection elements 211. In this embodiment, the solders 212 can be accommodated and constrained at the second areas 121c of the bearing surfaces 121a.

While this invention has been particularly illustrated and described in detail with respect to the preferred embodiments thereof, it will be clearly understood by those skilled in the art that it is not limited to the specific features and describes and various modifications and changes in form and details may be made without departing from the spirit and scope of this invention.

What is claimed is:

1. A semiconductor manufacturing method at least includes:
providing a carrier having a surface and a metallic layer formed on the surface, the metallic layer comprises a plurality of base areas and a plurality of outer lateral areas located outside the base areas;
forming a first photoresist layer on the metallic layer, wherein the first photoresist layer comprises a plurality of first openings;
forming a plurality of bearing portions at the first openings;
removing the first photoresist layer to reveal the bearing portions, wherein each bearing portion comprises a bearing surface having a first area and a second area;
forming a second photoresist layer on the metallic layer and covering the bearing portions with the second photoresist layer, wherein the second photoresist layer comprises a plurality of second openings for revealing the first areas of the bearing surfaces;
forming a plurality of connection portions at the second openings and covering the first areas of the bearing surfaces with the connection portions to make each connection portion connect with each bearing portion to form a snap bump;
removing the second photoresist layer to reveal the snap bumps; and
removing the outer lateral areas of the metallic layer to make the base areas of the metallic layer form a plurality of under bump metallurgy layers.

2. The semiconductor manufacturing method in accordance with claim 1, wherein each bearing portion comprises a first thickness, each connection portion comprises a second thickness larger than the first thickness.

3. The semiconductor manufacturing method in accordance with claim 1, wherein each bearing portion includes a first bearing layer and a second bearing layer.

4. The semiconductor manufacturing method in accordance with claim 1, wherein the material of the bearing portions is selected from one of gold, nickel or copper.

5. The semiconductor manufacturing method in accordance with claim 1, wherein the material of the connection portions is selected from one of gold, nickel or copper.

6. The semiconductor manufacturing method in accordance with claim 1, wherein the material of the under bump metallurgy layers is selected from one of titanium/copper, titanium-tungsten/copper or titanium-tungsten/gold.
